(19) United States
(12) Patent Application Publication
(10) Pub. No.: US 2020/0264320 A1
(43) Pub. Date: Aug. 20, 2020

(54) RADIATION DETECTOR AND RADIATION DETECTION APPARATUS

(71) Applicant: KABUSHIKI KAISHA TOSHIBA, Minato-ku (JP)

(72) Inventors: Fumihiko AIGA, Kawasaki (JP); Rei Hasegawa, Yokohama (JP); lsao Takasu, Setagaya (JP)

(73) Assignee: KABUSHIKI KAISHA TOSHIBA, Minato-ku (JP)

(21) Appl. No.: 16/564,753

(22) Filed: Sep. 9, 2019

(30) Foreign Application Priority Data
Feb. 19, 2019 (JP) 2019-027776

(51) Int. Cl. G01T 1/20; H01L 27/30

(52) U.S. Cl. CPC G01T 1/2006; G01T 1/2002; H01L 27/308; G01T 1/2018

(57) ABSTRACT

A radiation detector includes a first scintillator, a second scintillator, a first photoelectric conversion layer, and a second photoelectric conversion layer. The first scintillator converts β rays into first scintillation light. The second scintillator converts the β rays into second scintillation light. The first photoelectric conversion layer is provided between the first scintillator and the second scintillator and converts the first scintillation light into electric charges. The second photoelectric conversion layer is provided between the first photoelectric conversion layer and the second scintillator and converts the second scintillation light into electric charges. The first scintillator, the second scintillator, the first photoelectric conversion layer, and the second photoelectric conversion layer are each formed with an organic material as a main component. The thickness of the second scintillator is larger than the thickness of the first scintillator.

### CROSS-REFERENCE TO RELATED APPLICATIONS

This application is based upon and claims the benefit of priority from Japanese Patent Application No. 2019-027776, filed on Feb. 19, 2019; the entire contents of which are incorporated herein by reference.

### FIELD

Embodiments described herein relate generally to a radiation detector and a radiation detection apparatus.

### BACKGROUND

Radiation detectors that detect electric charges resulting from conversion by a photoelectric conversion layer have been known. For example, the configuration in which the photoelectric conversion layer is arranged between a pair of electrode layers and the electric charges resulting from conversion by the photoelectric conversion layer are read through electrodes have been known. Apparatuses that detect β-rays as radiation have been known.

Conventionally, a plastic scintillator of a single layer or plastic scintillators arranged in an adjacent and contact manner has/have been used as a β-ray detector. It has been therefore difficult to detect β-rays in at least some energy bands among β-rays in various energy bands.

### BRIEF DESCRIPTION OF THE DRAWINGS

FIG. 1 is a schematic diagram of a radiation detection apparatus;

FIG. 2 is a schematic diagram of a radiation detector;

FIG. 3 is a table illustrating a simulation result of relations between the thicknesses of scintillators and absorption energies;

FIG. 4 is a flowchart of the procedure of information processing;

FIG. 5 is a schematic diagram illustrating another example of the radiation detector; and

FIG. 6 is a block diagram illustrating an example of the hardware configuration of the radiation detection apparatus.

### DETAILED DESCRIPTION

A radiation detector includes a first scintillator, a second scintillator, a first photoelectric conversion layer, and a second photoelectric conversion layer. The first scintillator converts β rays into first scintillation light. The second scintillator converts the β rays into second scintillation light. The first photoelectric conversion layer is provided between the first scintillator and the second scintillator and converts the first scintillation light into electric charges. The second photoelectric conversion layer is provided between the first photoelectric conversion layer and the second scintillator and converts the second scintillation light into electric charges. The first scintillator, the second scintillator, the first photoelectric conversion layer, and the second photoelectric conversion layer are each formed with an organic material as a main component. The thickness of the second scintillator is larger than the thickness of the first scintillator.

Hereinafter, embodiments will be described in detail with reference to the accompanying drawings.

### First Embodiment

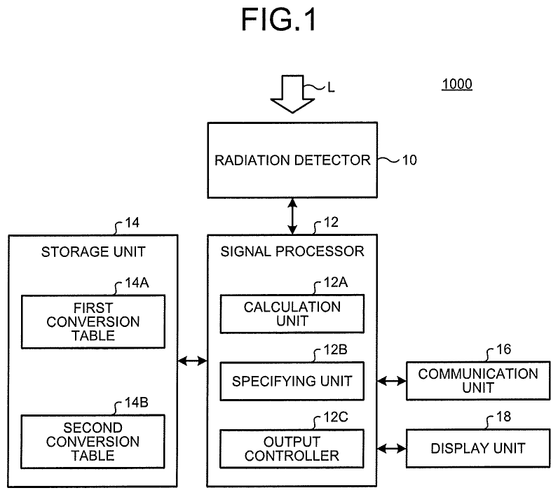

FIG. 1 is a schematic diagram of an example of a radiation detection apparatus 1000.

The radiation detection apparatus 1000 includes a radiation detector 10, a signal processor 12, a storage unit 14, a communication unit 16, and a display unit 18. The radiation detector 10, the storage unit 14, the communication unit 16, and the display unit 18 are connected to the signal processor 12 so as to transmit and receive pieces of data and signals.

The radiation detector 10 outputs an output signal in accordance with incident β rays L. The signal processor 12 specifies detection energy of the β rays L incident on the radiation detector 10 using the output signal acquired from the radiation detector 10.

A type of a radioactive material emitting the β rays L as a detection target by the radiation detector 10 in the embodiment is not limited. For example, the radioactive material emitting the β rays L as the detection target by the radiation detector 10 is at least one type of I-131, Cs-134, Cs-137, Sr-90, and the like. In the embodiment, a plurality of types of radioactive materials emitting the β rays L are the detection targets by the radiation detector 10, as an example.

The storage unit 14 stores therein various types of data. The communication unit 16 communicates with an external apparatus via a network or the like. In the embodiment, the communication unit 16 transmits, to the external apparatus, information indicating a specified result by the signal processor 12. The display unit 18 displays various types of images. In the embodiment, the display unit 18 displays the information indicating the specified result by the signal processor 12.

The radiation detection apparatus 1000 may include any one of the display unit 18 and the communication unit 16. The units configuring the radiation detection apparatus 1000 may be accommodated in one housing or may be arranged in a plurality of housings in a divided manner.

### Radiation Detector 10

First, the radiation detector 10 will be described.

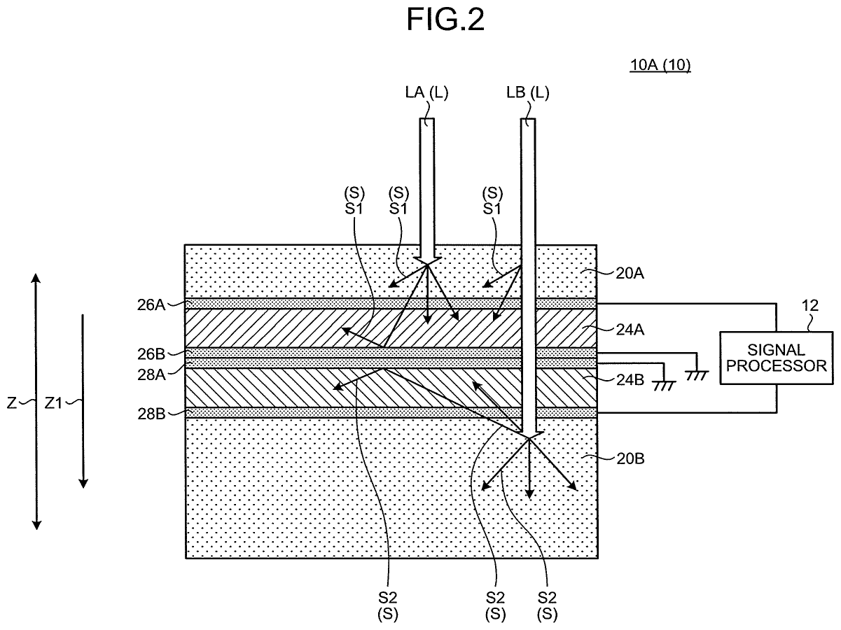

FIG. 2 is a schematic diagram illustrating a radiation detector 10A. The radiation detector 10A is an example of the radiation detector 10.

### Radiation Detector 10A

The radiation detector 10A includes a first scintillator 20A, a second scintillator 20B, a first photoelectric conversion layer 24A, a second photoelectric conversion layer 24B, a first electrode layer 26A, a second electrode layer 26B, a third electrode layer 28A, and a fourth electrode layer 28B.

The radiation detector 10A is a multilayer body formed by laminating the second scintillator 20B, the fourth electrode layer 28B, the second photoelectric conversion layer 24B, the third electrode layer 28A, the second electrode layer 26B, the first photoelectric conversion layer 24A, the first electrode layer 26A, and the first scintillator 20A in this order.

First, the first scintillator 20A and the second scintillator 20B will be described.

The first scintillator 20A converts the β rays L into first scintillation light S1. That is to say, the first scintillator 20A converts the β rays L incident on the first scintillator 20A into the first scintillation light S1 as scintillation light (photons) having a lower energy than that of the β rays L.

The second scintillator 20B converts the β rays L into second scintillation light S2. That is to say, the second scintillator 20B converts the β rays L incident on the second scintillator 20B into the second scintillation light S2 as scintillation light (photons) having a lower energy than that of the β rays L.

The scintillation light converted by the first scintillator 20A is referred to as the first scintillation light S1 for description. The scintillation light converted by the second scintillator 20B is referred to as the second scintillation light S2 for description. When the first scintillation light S1 and the second scintillation light S2 are collectively referred for description, they are simply referred to as scintillation light S.

The first scintillator 20A and the second scintillator 20B are formed with scintillator materials. The scintillator materials are materials emitting the scintillation light S upon incidence of the β rays L. The first scintillator 20A and the second scintillator 20B are formed with scintillator materials containing organic materials as main components. The main component indicates a content that is equal to or higher than 70%. That is to say, the first scintillator 20A and the second scintillator 20B are formed with organic scintillators as the main components.

Examples of the organic scintillator include aromatic molecular crystals of anthracene (C₁₄H₁₀), stilbene (C₁₄H₁₂), naphthalene (C₁₀H₈), and the like and mixtures provided by dissolving, in plastic or organic liquid, the aromatic molecular crystals. Among them, a plastic scintillator is preferably used for the first scintillator 20A and the second scintillator 20B from the viewpoint of capturing performance of the β rays, easy workability, and the like.

Formation of the first scintillator 20A and the second scintillator 20B with the organic scintillators as the main components enables the densities of the first scintillator 20A and the second scintillator 20B to be in a range that is equal to or higher than 1.0 g/cm³ and equal to or lower than 2.0 g/cm³.

It is sufficient that the densities of the first scintillator 20A and the second scintillator 20B are adjusted to the above-mentioned range by adjusting the types of the organic scintillators forming the first scintillator 20A and the second scintillator 20B. When the first scintillator 20A and the second scintillator 20B contain a plurality of types of organic scintillators, the densities thereof may be adjusted by adjusting the contents of the types of organic scintillators.

The types of the organic scintillators as the main components of the first scintillator 20A and the second scintillator 20B may be the same as or different from each other. It is sufficient that the densities of the first scintillator 20A and the second scintillator 20B are in the above-mentioned range, and they may be the same as or different from each other.

At least parts of wavelength regions of the first scintillation light S1 and the second scintillation light S2 may or may not be overlapped with each other. When the at least parts of the wavelength regions of the first scintillation light S1 and the second scintillation light S2 are not overlapped with each other, the first scintillator 20A and the second scintillator 20B can be made to emit the scintillation light S of different colors. The wavelength regions of the first scintillation light S1 and the second scintillation light S2 can be set by adjusting constituent materials of the first scintillator 20A and the second scintillator 20B.

In the embodiment, the thickness of the second scintillator 20B is larger than the thickness of the first scintillator 20A.

The thicknesses of the first scintillator 20A and the second scintillator 20B indicate the thicknesses (lengths) in the lamination direction (direction of an arrow Z) of the second scintillator 20B, the second photoelectric conversion layer 24B, the first photoelectric conversion layer 24A, and the first scintillator 20A in the radiation detector 10A.

As described above, in the embodiment, the first scintillator 20A is arranged on the upstream side relative to the second scintillator 20B in the incident direction of the β rays L (see the direction of an arrow Z1, hereinafter, referred to as an incident direction Z1 in some case). To be specific, the first scintillator 20A is arranged on the upstream side, in the incident direction Z1 of the β rays L, relative to the second scintillator 20B, the second photoelectric conversion layer 24B, and the first photoelectric conversion layer 24A.

That is to say, in the embodiment, the second scintillator 20B having the larger thickness is arranged on the downstream side, in the incident direction Z1 of the β rays L, relative to the first scintillator 20A having the smaller thickness. The first scintillator 20A arranged on the upstream side in the incident direction Z1 of the β rays L can therefore covert, into the first scintillation light S1, β rays LA in a lower energy band preferentially toβ rays LB in a higher energy band. The second scintillator 20B arranged on the downstream side in the incident direction Z1 of the β rays L can covert, into the second scintillation light S2, the β rays LB in the higher energy band preferentially to the β rays LA in the lower energy band (details thereof will be described later).

The incident direction Z1 of the β rays L is identical to the thickness direction of the radiation detector 10A. The thickness direction is identical to the lamination direction of the layers (the second scintillator 20B, the second photoelectric conversion layer 24B, the first photoelectric conversion layer 24A, the first scintillator 20A, and the like) configuring the radiation detector 10A.

It is sufficient that the thickness of the second scintillator 20B is larger than the thickness of the first scintillator 20A.

Upper limit values of the thicknesses of the first scintillator 20A and the second scintillator 20B are not limited. The thicknesses of the first scintillator 20A and the second scintillator 20B are preferably as follows, for example.

To be specific, the thickness of the first scintillator 20A is preferably smaller than a thickness capable of converting γ rays into the first scintillation light S1. That is to say, the thickness of the first scintillator 20A is preferably set such that the first scintillator 20A has a difficulty in converting the γ rays into the first scintillation light S1.

Similarly, the thickness of the second scintillator 20B is preferably smaller than a thickness capable of converting the γ rays into the second scintillation light S2. That is to say, the thickness of the second scintillator 20B is preferably set such that the second scintillator 20B has a difficulty in converting the γ rays into the second scintillation light S2.

It is sufficient that the thicknesses of the first scintillator 20A and the second scintillator 20B are appropriately adjusted in accordance with the types of the radioactive materials emitting the β rays L as the detection target by the radiation detector 10A in a range satisfying the above-mentioned relations.

For example, the radioactive materials emitting the p rays L as the detection target by the radiation detector 10A are supposed to be Sr-90 and Cs-137. That is to say, the β rays L as the detection target by the radiation detector 10A are supposed to beβ rays emitted from Sr-90 and Cs-137. In this case, preferably, the thickness of the first scintillator 20A is equal to or larger than 0.1 mm and equal to or smaller than 0.9 mm, and the thickness of the second scintillator 20B is equal to or larger than 1 mm and equal to or smaller than 4 mm.

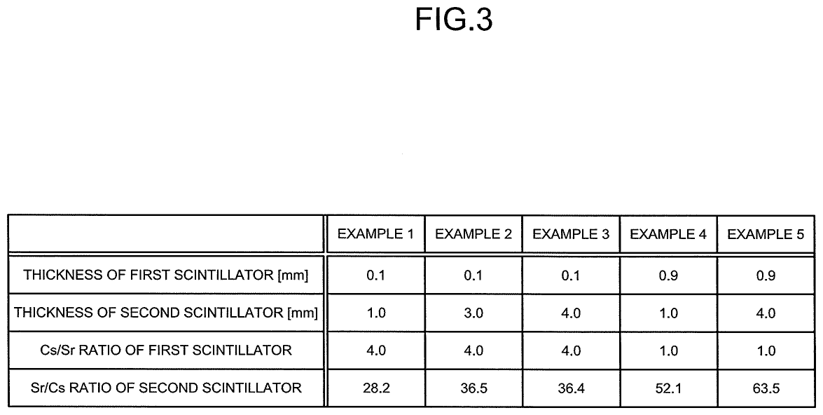

FIG. 3 is a table illustrating a simulation result of relations between the thicknesses of the first scintillator 20A and the second scintillator 20B and absorption energies when the β rays LB are incident on the radiation detector 10A.

With reference to FIG. 3, the β rays L emitted from each of the Sr-90 and Cs-137 were made to be incident on the radiation detector 10A. In FIG. 3, a Cs/Sr ratio of the first scintillator 20A indicates a ratio of the absorption amount of the β rays L emitted from Cs-137 relative to the absorption amount of the β rays L emitted from Sr-90, the β rays L having being absorbed by the first scintillator 20A In FIG. 3, a Sr/Cs ratio of the second scintillator 20B indicates a ratio of the absorption amount of the β rays L emitted from Sr-90 relative to the absorption amount of the β rays L emitted from Cs-137, the β rays L having being absorbed by the second scintillator 20B.

The energy band of the β rays L emitted from Cs-137 is lower than the energy band of the β rays L emitted from Sr-90.

In the radiation detector 10A in the embodiment, the first scintillator 20A arranged on the upstream side in the incident direction Z1 of the β rays L preferentially coverts, into the first scintillation light S1, the β rays LB in the lower energy band than that converted by the second scintillator 20B. On the other hand, in the radiation detector 10A, the second scintillator 20B arranged on the downstream side in the incident direction Z1 of the β rays L preferentially coverts, into the second scintillation light S2, the β rays LB in the higher energy band than that converted by the first scintillator 20A.

The thicknesses of the first scintillator 20A and the second scintillator 20B are preferably adjusted such that the Cs/Sr ratio of the first scintillator 20A is higher and the Sr/Cs ratio of the second scintillator 20B is higher.

As illustrated in FIG. 3, among combinations of the thicknesses of the first scintillator 20A and the second scintillator 20B in Example 1 to Example 5, combinations of the thicknesses in Example 1 to Example 3 are preferable, the combinations of the thicknesses in Example 2 and Example 3 are more preferable, and the combination of the thicknesses in Example 2 is the most preferable.

To be specific, the β rays L as the detection target by the radiation detector 10A are supposed to be the β rays L emitted from Sr-90 and Cs-137. In this case, as described above, a combination in which the thickness of the first scintillator 20A is equal to or larger than 0.1 mm and equal to or smaller than 0.9 mm and the thickness of the second scintillator 20B is equal to or larger than 1.0 mm and equal to or smaller than 4.0 mm is preferable. More preferably, the thickness of the first scintillator 20A is 0.1 mm, and the thickness of the second scintillator 20B is equal to or larger than 1.0 mm and equal to or smaller than 4.0 mm. Much more preferably, the thickness of the first scintillator 20A is 0.1 mm, and the thickness of the second scintillator 20B is 3.0 mm or 4.0 mm. Particularly preferably, the thickness of the first scintillator 20A is 0.1 mm, and the thickness of the second scintillator 20B is 3.0 mm.

Explanation is continued with reference to FIG. 2 again. Next, the first photoelectric conversion layer 24A and the second photoelectric conversion layer 24B will be described.

The first photoelectric conversion layer 24A is provided between the first scintillator 20A and the second scintillator 20B. The first photoelectric conversion layer 24A is arranged on the upstream side relative to the second photoelectric conversion layer 24B in the incident direction Z1 of the I rays L.

The first photoelectric conversion layer 24A converts the first scintillation light S1 into electric charges. The first photoelectric conversion layer 24A converts the first scintillation light S1 converted by the first scintillator 20A into the electric charges and is formed with an organic material as a main component.

The second photoelectric conversion layer 24B is provided between the first photoelectric conversion layer 24A and the second scintillator 20B. The second photoelectric conversion layer 24B is arranged on the downstream side relative to the first photoelectric conversion layer 24A in the incident direction Z1 of the β rays L. The second photoelectric conversion layer 24B converts the second scintillation light S2 into electric charges. The second photoelectric conversion layer 24B converts the second scintillation light S2 converted by the second scintillator 20B into the electric charges and is formed with an organic material as a main component.

The first photoelectric conversion layer 24A and the second photoelectric conversion layer 24B have, for example, bulk hetero-junction structures.

The bulk hetero-junction structure has, for example, a mixture of a p-type semiconductor material and an n-type semiconductor material. The bulk hetero-junction structure can enlarge a phase interface between a p-type semiconductor and an n-type semiconductor. An organic semiconductor layer of a bulk hetero-junction type has a microphase-separated structure of the p-type semiconductor material and the n-type semiconductor material. In the organic semiconductor layer, a phase of the p-type semiconductor and a phase of the n-type semiconductor are separated from each other.

The organic semiconductor layer contains, for example, a PN junction. The p-type semiconductor material includes, for example, at least one of polythiophene and a polythiophene derivative. These compounds are, for example, conductive polymers having a π-conjugated structure. Polythiophene and the polythiophene derivative have, for example, excellent stereoregularity. These materials have relatively high solubility in a solvent. Polythiophene and the polythiophene derivative have a thiophene framework. The p-type semiconductor material includes, for example, at least one selected from the group consisting of polyarylthiophene, polyalkylisothionaphthene, and polyethylenedioxythiophene. Polyarylthiophene as described above includes, for example, at least one of polyalkylthiophene such as poly(3-methylthiophene), poly(3-butylthiophene), poly(3-hexylthiophene), poly(3-octylthiophene), poly(3-decylthiophene), and poly(3-dodecylthiophene), poly(3-phenylthiophene), and poly(3-(p-alkylphenylthiophene).

Polyalkylisothionaphthene as described above includes, for example, at least one selected from the group consisting of poly(3-butylisothionaphthene), poly(3-hexylisothionaphthene), poly(3-octylisothionaphthene), and poly(3-decylisothionaphthene). The polythiophene derivative is exemplified as the p-type semiconductor material and includes, for example, at least one selected from the group consisting of carbazole, benzothiadiazole, and a thiophene copolymer. The thiophene copolymer includes, for example, polyN-9″-hepta-decanyl-2,7-carbazole-alt-5,5-(4′,7′-di-2-thienyl-2′,1′,3′-benzothiadiazole) (PCDTBT). Inclusion of polythiophene or the polythiophene derivative as the p-type semiconductor material can provide high conversion efficiency, for example.

The n-type semiconductor material includes, for example, fullerene and a fullerene derivative. The fullerene derivative has a fullerene framework. The fullerene and the fullerene derivative include, for example, at least one selected from the group consisting of C60, C70, C76, C78, and C84. The fullerene derivative includes fullerene oxide. The fullerene oxide is any of these fullerenes whose carbon atoms are at least partly oxidized.

The carbon atoms in the fullerene framework of the fullerene derivative are partly modified with optional functional groups. The fullerene derivative may contain a ring formed by the functional groups bonded to each other. The fullerene derivative may include a fullerene-bonded polymer. The n-type semiconductor material preferably includes a fullerene derivative having a functional group with high affinity to a solvent. The compound has high solubility in the solvent. The functional group contained in the fullerene derivative may include, for example, at least any one selected from the group consisting of a hydrogen atom, a hydroxyl group, a halogen atom, an alkyl group, an alkenyl group, a cyano group, an aromatic hydrocarbon group, and an aromatic heterocyclic group. The halogen atom includes, for example, at least one selected from the group consisting of a fluorine atom and a chlorine atom. The alkyl group includes, for example, at least one selected from the group consisting of a methyl group and an ethyl group. The alkenyl group includes, for example, a vinyl group. The alkoxy group includes, for example, at least one selected from the group consisting of a methoxy group and an ethoxy group. The aromatic hydrocarbon group includes, for example, at least one selected from the group consisting of a phenyl group and a naphthyl group. The aromatic heterocyclic group includes, for example, at least one selected from the group consisting of a thienyl group and a pyridyl group.

The fullerene derivative may include, for example, fullerene hydride. The fullerene hydride includes, for example, C60H36 and C70H36. The fullerene derivative includes, for example, fullerene oxide. In the fullerene oxide, C60 or C70 is oxidized. The fullerene derivative may include, for example, a fullerene metal complex.

The fullerene derivative may include, for example, at least one selected from the group consisting of 6,6-phenyl-C61-butyric acid methyl ester 60PCBM, 6,6-phenyl-C71-butyric acid methyl ester 70PCBM, indene-C60 bis-adduct (60ICBA), dihydronaphthyl-C60 bis-adduct (60NCBA), and dihydronaphthyl-C70 bis-adduct (70NCBA). 60PCBM is unmodified fullerene. 60PCBM has high optical carrier mobility. Examples of the p-type semiconductor material and the n-type semiconductor material include low molecular compounds such as merocyanine compounds, squarylium compounds, phthalocyanine compounds, quinacridone compounds, and perylene compounds.

The organic materials as the main components of the first photoelectric conversion layer 24A and the second photoelectric conversion layer 24B may be the same as or different from each other.

Formation of the first photoelectric conversion layer 24A and the second photoelectric conversion layer 24B with the organic materials as the main components enables the densities of the first photoelectric conversion layer 24A and the second photoelectric conversion layer 24B to be in a range that is equal to or higher than 1.0 g/cm³ and equal to or lower than 2.0 g/cm³.

It is sufficient that the densities of the first photoelectric conversion layer 24A and the second photoelectric conversion layer 24B are adjusted to the above-mentioned range by adjusting the types of the organic materials forming the first photoelectric conversion layer 24A and the second photoelectric conversion layer 24B. When the first photoelectric conversion layer 24A and the second photoelectric conversion layer 24B are formed with a plurality of types of organic materials as the main components, the densities thereof may be adjusted by adjusting the contents of the organic materials.

It is sufficient that regions corresponding to pixel regions in the first photoelectric conversion layer 24A and the second photoelectric conversion layer 24B are previously defined by adjusting arrangement or the like of the first electrode layer 26A, the second electrode layer 26B, the third electrode layer 28A, and the fourth electrode layer 28B.

The thicknesses of the first photoelectric conversion layer 24A and the second photoelectric conversion layer 24B are not limited. The thicknesses of the first photoelectric conversion layer 24A and the second photoelectric conversion layer 24B are, for example, in a range that is equal to or larger 1 nm and equal to or smaller than 1 mm.

The thicknesses of the first photoelectric conversion layer 24A and the second photoelectric conversion layer 24B may be the same as or different from each other. The densities of the first photoelectric conversion layer 24A and the second photoelectric conversion layer 24B may be the same as or different from each other.

Next, the first electrode layer 26A, the second electrode layer 26B, the third electrode layer 28A, and the fourth electrode layer 28B will be described.

The first electrode layer 26A and the second electrode layer 26B are arranged on both end surfaces of the first photoelectric conversion layer 24A in the thickness direction. To be specific, the first electrode layer 26A is arranged on the end surface of the first photoelectric conversion layer 24A on the upstream side in the incident direction Z1 of the β rays L. The second electrode layer 26B is arranged on the end surface of the first photoelectric conversion layer 24A on the downstream side in the incident direction Z1 of the β rays L.

To be specific, the first electrode layer 26A is arranged between the first scintillator 20A and the first photoelectric conversion layer 24A. The second electrode layer 26B is arranged between the first photoelectric conversion layer 24A and the second photoelectric conversion layer 24B. That is to say, the first photoelectric conversion layer 24A is arranged between the first electrode layer 26A and the second electrode layer 26B.

The first electrode layer 26A transmits at least a part of the β rays L and transmits at least a part of the first scintillation light S1. The expression “transmit” indicates transmission of incident light of equal to or higher than 50%, and preferably equal to or higher than 80%. The incident light is the β rays L and the scintillation light S.

The second electrode layer 26B transmits at least a part of the β rays L and reflects at least a part of the first scintillation light S1. The expression “reflect” indicates reflection of the incident light of equal to or higher than 50%, and preferably equal to or higher than 80%.

The first electrode layer 26A and the second electrode layer 26B are formed with materials satisfying the above-mentioned characteristics and having conductivity. The first electrode layer 26A and the second electrode layer 26B are formed with, for example, materials selected from indium tin oxide (ITO), graphene, ZnO, aluminum, gold, magnesium-silver alloy, magnesium-indium alloy, aluminum-doped zinc oxide, and indium zinc oxide.

The thicknesses of the first electrode layer 26A and the second electrode layer 26B are not limited. The thicknesses of the first electrode layer 26A and the second electrode layer 26B are, for example, 50 nm and 150 nm, respectively.

The third electrode layer 28A and the fourth electrode layer 28B are arranged on both end surfaces of the second photoelectric conversion layer 24B in the thickness direction. To be specific, the third electrode layer 28A is arranged on the end surface of the second photoelectric conversion layer 24B on the upstream side in the incident direction Z1 of the β rays L. The fourth electrode layer 28B is arranged on the end surface of the second photoelectric conversion layer 24B on the downstream side in the incident direction Z1 of the β rays L.

To be specific, the third electrode layer 28A is arranged between the second photoelectric conversion layer 24B and the second electrode layer 26B. The fourth electrode layer 28B is arranged between the second photoelectric conversion layer 24B and the second scintillator 20B. That is to say, the second photoelectric conversion layer 24B is arranged between the third electrode layer 28A and the fourth electrode layer 28B.

The third electrode layer 28A transmits at least a part of the β rays L and reflects at least a part of the second scintillation light S2. The fourth electrode layer 28B transmits at least a part of the 0 rays L and transmits at least a part of the second scintillation light S2.

The third electrode layer 28A and the fourth electrode layer 28B are formed with materials satisfying the above-mentioned characteristics and having conductivity. The third electrode layer 28A and the fourth electrode layer 28B are formed with, for example, materials selected from indium tin oxide (ITO), graphene, ZnO, aluminum, gold, magnesium-silver alloy, magnesium-indium alloy, aluminum-doped zinc oxide, and indium zinc oxide.

The thicknesses of the third electrode layer 28A and the fourth electrode layer 28B are not limited. The thicknesses of the third electrode layer 28A and the fourth electrode layer 28B are, for example, 150 nm and 50 nm, respectively.

In the embodiment, the first electrode layer 26A and the fourth electrode layer 28B are electrically connected to the signal processor 12. The second electrode layer 26B and the third electrode layer 28A are grounded. The second electrode layer 26B and the third electrode layer 28A may be configured as a common electrode.

### Actions of Radiation Detector 10A

Next, actions of the radiation detector 10A will be described.

The β rays L are incident on the radiation detector 10A and reach the first scintillator 20A. The first scintillator 20A converts, into the first scintillation light S1, the β rays L incident on the first scintillator 20A.

The first scintillation light S1 converted by the first scintillator 20A reaches the first photoelectric conversion layer 24A. The first photoelectric conversion layer 24A converts the incident first scintillation light S1 into electric charges. An output signal with the electric charges resulting from conversion by the first photoelectric conversion layer 24A is output to the signal processor 12 through the first electrode layer 26A.

As described above, the thickness of the first scintillator 20A is smaller than the thickness of the second scintillator 20B.

As the energy band of the β rays LB is higher, the conversion efficiency into the first scintillation light S1 by the first scintillator 20A is lower and the probability that the β rays LB pass through the first scintillator 20A and reach the second scintillator 20B is higher. The first scintillator 20A coverts, into the first scintillation light S1, the β rays LA in the lower energy band out of the β rays L incident on the radiation detector 10A preferentially to the β rays LB in the higher energy band.

As described above, the first electrode layer 26A transmits at least a part of the 13 rays L and transmits at least a part of the first scintillation light S1. The second electrode layer 26B transmits at least a part of the β rays L and reflects at least a part of the first scintillation light S1.

The first scintillation light S1 converted by the first scintillator 20A reaches the first photoelectric conversion layer 24A through the first electrode layer 26A. The first scintillation light S1 that has reached the first photoelectric conversion layer 24A and has reached the second electrode layer 26B is reflected by the second electrode layer 26B and reaches the first photoelectric conversion layer 24A again.

The first electrode layer 26A and the second electrode layer 26B have the above-mentioned characteristics, so that the first photoelectric conversion layer 24A can convert the first scintillation light S1 into the electric charges efficiently.

On the other hand, at least a part of the β rays L incident on the radiation detector 10A passes through the first scintillator 20A and reaches the second scintillator 20B.

Theβ rays L incident on the second scintillator 20B are converted into the second scintillation light S2 by the second scintillator 20B and reach the second photoelectric conversion layer 24B. The second photoelectric conversion layer 24B converts the incident second scintillation light S2 into electric charges. The electric charges resulting from conversion by the second photoelectric conversion layer 24B are output, as an output signal, to the signal processor 12 through the fourth electrode layer 28B.

As described above, the thickness of the second scintillator 20B is larger than the thickness of the first scintillator 20A. The second scintillator 20B can therefore convert, into the second scintillation light S2, the β rays L that have passed through the first scintillator 20A and have reached the second scintillator 20B. That is to say, the second scintillator 20B coverts, into the second scintillation light S2, the β rays LB in the higher energy band than that converted by the first scintillator 20A. That is to say, the second scintillator 20B coverts, into the second scintillation light S2, the β rays LB in the higher energy band out of the β rays L incident on the radiation detector 10A preferentially to the β rays LA in the lower energy band.

As described above, the third electrode layer 28A transmits at least a part of the β rays L and reflects at least a part of the second scintillation light S2. The fourth electrode layer 28B transmits at least a part of the β rays L and transmits at least a part of the second scintillation light S2.

The second scintillation light S2 converted by the second scintillator 20B reaches the second photoelectric conversion layer 24B through the fourth electrode layer 28B. The second scintillation light S2 that has reached the second photoelectric conversion layer 24B and has reached the third electrode layer 28A is reflected by the third electrode layer 28A and reaches the second photoelectric conversion layer 24B again.

The third electrode layer 28A and the fourth electrode layer 28B have the above-mentioned characteristics, so that the second photoelectric conversion layer 24B can convert the second scintillation light S2 into the electric charges efficiently.

In the radiation detector 10A in the embodiment, the first scintillator 20A preferentially coverts, into the first scintillation light S1, the β rays LA in the lower energy band, and the second scintillator 20B preferentially coverts, into the second scintillation light S2, the β rays LB in the higher energy band. The radiation detector 10A in the embodiment can therefore detect the β rays L in various energy bands.

### Signal Processor 12

Explanation is continued with reference to FIG. 1 again. Next, the signal processor 12 will be described.

As described above, the signal processor 12 is electrically connected to the radiation detector 10, the storage unit 14, the communication unit 16, and the display unit 18.

The radiation detector 10 is the radiation detector 10A (see FIG. 2) for description as an example. It is sufficient that the signal processor 12 performs the same processing also when the radiation detector 10 is a radiation detector 10B.

The signal processor 12 receives a first output signal from the first photoelectric conversion layer 24A. The signal processor 12 receives a second output signal from the second photoelectric conversion layer 24B.

The first output signal is a signal indicating the electric charges resulting from conversion by the first photoelectric conversion layer 24A. In other words, the first output signal is average detection energy of the first scintillation light S1 detected by the first photoelectric conversion layer 24A. The signal processor 12 converts the amount of the electric charges detected by the first photoelectric conversion layer 24A into a signal that can be measured by a charge amplifier or the like and further performs A/D conversion to provide the first output signal. In the embodiment, the signal processor 12 receives the first output signal from the first photoelectric conversion layer 24A for description in order to simplify the description.

The second output signal is a signal indicating the electric charges resulting from conversion by the second photoelectric conversion layer 24B. In other words, the second output signal is average detection energy of the second scintillation light S2 detected by the second photoelectric conversion layer 24B. The signal processor 12 converts the amount of the electric charges detected by the second photoelectric conversion layer 24B into a signal that can be measured by a charge amplifier or the like and further performs A/D conversion to provide the second output signal. In the embodiment, the signal processor 12 receives the second output signal from the second photoelectric conversion layer 24B for description in order to simplify the description.

As described above, the first scintillator 20A preferentially coverts, into the first scintillation light S1, the β rays L in the lower energy band than that converted by the second scintillator 20B. On the other hand, the second scintillator 20B preferentially coverts, into the second scintillation light S2, the β rays LB in the higher energy band than that converted by the first scintillator 20A.

The second output signal output from the second photoelectric conversion layer 24B that converts the second scintillation light S2 into the electric charges is a signal provided by converting, into the electric charges, the β rays L in the higher energy band than that of the first output signal output from the first photoelectric conversion layer 24A that converts the first scintillation light S1 into the electric charges.

The signal processor 12 specifies a detection result of the β rays L using the first output signal and the second output signal. That is to say, the signal processor 12 specifies the detection result of the β rays L using the first output signal and the second output signal as the output signals provided by converting the β rays L in the different energy bands into the electric charges.

To be specific, the signal processor 12 specifies the detection result of the β rays L using the first output signal output from the first photoelectric conversion layer 24A and the second output signal output from the second photoelectric conversion layer 24B.

Specifically, the signal processor 12 includes a calculation unit 12A, a specifying unit 12B, and an output controller 12C. The calculation unit 12A, the specifying unit 12B, and the output controller 12C are implemented by, for example, one or a plurality of processors. For example, the above-mentioned units may be implemented by causing the processor such as a central processing unit (CPU) to execute computer programs, that is, by software. The above-mentioned units may be implemented by a processor such as an exclusive integrated circuit (IC), that is, hardware. The above-mentioned units may be implemented by the software and the hardware in combination. When the processors are used, each processor may implement one of the units or two or more of the units.

The calculation unit 12A calculates a signal ratio between the first output signal and the second output signal, the signal ratio being an evaluation value of the β rays L incident on the radiation detector 10. The signal ratio is, to be specific, a value provided by dividing the second output signal by the first output signal. That is to say, the evaluation value is expressed by the following equation (1).

Evaluation value=Second output signal/First output signal Equation (1)

The first output signal is an output signal with the electric charges resulting from conversion by the first photoelectric conversion layer 24A. The second output signal is an output signal with the electric charges resulting from conversion by the second photoelectric conversion layer 24B. The output signals correspond to average detection energies. The average detection energy indicates an average value of energy that is detected per unit time.

To be specific, the calculation unit 12A calculates the average detection energies by the first photoelectric conversion layer 24A and the second photoelectric conversion layer 24B as the first output signal and the second output signal for each predetermine time interval. The calculation unit 12A calculates the evaluation value as the value provided by dividing the second output signal by the first output signal.

Use of this calculation method provides an advantage that the evaluation value largely varies when the β rays L start reaching the second photoelectric conversion layer 24B and change (that is, difference) in the average detection energy relative to change in the incident energy of the β rays L is easy to be detected.

The specifying unit 12B specifies the detection energy of the βαrays L using the evaluation value calculated by the calculation unit 12A and a conversion table stored in the storage unit 14.

The conversion table is previously stored in the storage unit 14. The storage unit 14 previously stores therein a first conversion table 14A and a second conversion table 14B as the conversion table. It is sufficient that the storage unit 14 previously stores therein at least the first conversion table 14A.

The first conversion table 14A is a conversion table in which the evaluation value, the types of the radioactive materials emitting the β rays L, and the incident energy of the β rays L are associated with one another.

For example, the signal processor 12 uses the radiation detector 10 (for example, the radiation detector 10A) used for detection to previously measure the incident energy of the β rays L incident on the radiation detector 10, the types of the radioactive materials emitting the β rays, and the evaluation value as the signal ratio between the first output signal and the second output signal output from the radiation detector 10. The signal processor 12 previously creates the first conversion table 14A, containing the detection result indicating a relation among the incident energy of the β rays L, the types of the radioactive materials emitting the β rays, and the evaluation value.

The signal processor 12 may previously create the first conversion table 14A by simulation. The signal processor 12 may previously create the first conversion table 14A using Monte Carlo simulation in activation or calibration of the radiation detection apparatus 1000.

An external apparatus or the like may create the first conversion table 14A. The storage unit 14 previously stores therein the first conversion table 14A.

The external apparatus or the like may previously store therein the first conversion table 14A. The specifying unit 12B may specify the detection energy of the β rays L by reading the first conversion table 14A from the external apparatus. The specifying unit 12B may output the evaluation value calculated by the calculation unit 12A to the external apparatus and acquire the detection energy of the β rays L from the external apparatus to specify the detection energy. In this case, it is sufficient that the external apparatus reads, from the first conversion table 14A, the types of the radioactive materials emitting the β rays L and the incident energy of the β rays L that correspond to the evaluation value received from the specifying unit 12B and transmits them to the radiation detection apparatus 1000.

The first conversion table 14A may be in any form of a table, a function, a diagram, and a database as long as it indicates the relation among the incident energy of the β rays L incident on the radiation detector 10, the types of the radioactive materials emitting the β rays, and the evaluation value.

When the energy of the β rays L incident on the radiation detector 10 is small or when the energy band of the β rays L is low, the β rays L do not reach the second scintillator 20B in some cases.

In the embodiment, the storage unit 14 previously stores therein the second conversion table 14B. The second conversion table 14B is a conversion table in which the first output signal from the first photoelectric conversion layer 24A, the types of the radioactive materials emitting the β rays L, and the incident energy of the β rays L are associated with one another.

For example, the β rays L with low energy to the extent that they reach the first scintillator 20A but do not reach the second scintillator 20B are emitted to the radiation detector 10 (for example, the radiation detector 10A) to be used for detection. Then, a relation among the first output signal output from the first photoelectric conversion layer 24A of the radiation detector 10, the energy of the β rays L emitted to the radiation detector 10, and the types of the radioactive materials emitting the β rays L is previously measured. It is sufficient that the signal processor 12 previously creates the second conversion table 14B using a measurement result and previously stores it in the storage unit 14.

An external apparatus or the like may create the second conversion table 14B. The storage unit 14 previously stores therein the second conversion table 14B.

The specifying unit 12B specifies, as a detection result of the β rays L, the types of the radioactive materials emitting the β rays L and the incident energy that correspond to the evaluation value calculated by the calculation unit 12A in the first conversion table 14A.

When the β rays L incident on the first photoelectric conversion layer 24A and the second photoelectric conversion layer 24B lose their energies in the first photoelectric conversion layer 24A and the second photoelectric conversion layer 24B, the amounts of the electric charges that are generated in the first photoelectric conversion layer 24A and the second photoelectric conversion layer 24B are proportional to the energies of the β rays L incident on the first photoelectric conversion layer 24A and the second photoelectric conversion layer 24B, respectively. Use of the evaluation value calculated by the calculation unit 12A, the first conversion table 14A, and the second conversion table 14B can specify the detection result of the β rays L incident on the radiation detector 10A by the radiation detector 10A.

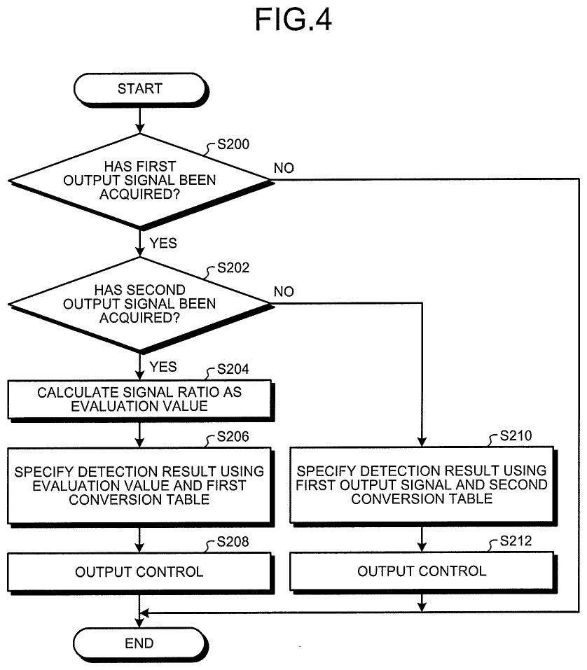

Next, an example of the procedure of information processing that the signal processor 12 executes will be described. FIG. 4 is a flowchart illustrating an example of the procedure of the information processing that the signal processor 12 executes.

First, it is determined whether the calculation unit 12A has acquired the first output signal from the first photoelectric conversion layer 24A of the radiation detector 10A (step S200). When negative determination is made at step S200 (No at step S200), this routine is ended. When positive determination is made at step S200 (Yes at step S200), the process proceeds to step S202.

At S202, it is determined whether the calculation unit 12A has acquired the second output signal from the second photoelectric conversion layer 24B (step S202).

When positive determination is made at step S202 (Yes at step S202), the process proceeds to step S204. At step S204, the signal ratio between the first output signal acquired at step S200 and the second output signal acquired at steps S202 is calculated as the evaluation value (step S204).

Then, the specifying unit 12B specifies, as the detection result, the types of the radioactive materials and the incident energy using the evaluation value calculated at step S204 and the first conversion table 14A (step S206).

Subsequently, the output controller 12C controls to output information indicating a specification result specified at step S206 to the communication unit 16 and the display unit 18 (step S208). The processing at step S208 causes the information indicating the detection result to be transmitted to the external apparatus from the communication unit 16. The processing at step S208 causes the information indicating the detection result to be displayed on the display unit 18. Then, this routine is ended.

On the other hand, when negative determination is made at step S202 (No at step S202), the process proceeds to step S210. At step S210, the specifying unit 12B specifies, as a detection result, the types of the radioactive materials and the incident energy using the first output signal acquired at step S200 and the second conversion table 14B (step S210). For example, the specifying unit 12B specifies, as the detection result, the types of the radioactive materials and the incident energy that correspond to the first output signal acquired at step S200 in the second conversion table 14B.

Subsequently, the output controller 12C controls to output information indicating the detection result specified at step S210 to the communication unit 16 and the display unit 18 (step S212). The processing at step S212 causes the information indicating the detection result to be transmitted to the external apparatus from the communication unit 16.

The processing at step S212 causes the information indicating the detection result to be displayed on the display unit 18. Then, this routine is ended.

As described above, the radiation detector 10A in the embodiment includes the first scintillator 20A, the second scintillator 20B, the first photoelectric conversion layer 24A, and the second photoelectric conversion layer 24B. The first scintillator 20A converts the β rays L into the first scintillation light S1. The second scintillator 20B converts the β rays L into the second scintillation light S2. The first photoelectric conversion layer 24A is provided between the first scintillator 20A and the second scintillator 20B and converts the first scintillation light S1 into the electric charges. The second photoelectric conversion layer 24B is provided between the first photoelectric conversion layer 24A and the second scintillator 20B and converts the second scintillation light S2 into the electric charges. The first scintillator 20A, the second scintillator 20B, the first photoelectric conversion layer 24A, and the second photoelectric conversion layer 24B are formed with the organic materials as the main components. The thickness of the second scintillator 20B is larger than the thickness of the first scintillator 20A.

Thus, in the radiation detector 10A in the embodiment, the first scintillator 20A, the second scintillator 20B, the first photoelectric conversion layer 24A, and the second photoelectric conversion layer 24B are formed with the organic materials as the main components.

Formation of the first scintillator 20A, the second scintillator 20B, the first photoelectric conversion layer 24A, and the second photoelectric conversion layer 24B with the organic materials as the main components can increase the densities thereof in comparison with the case in which they are formed with inorganic materials as the main components. The first scintillator 20A, the second scintillator 20B, the first photoelectric conversion layer 24A, and the second photoelectric conversion layer 24B can therefore be made to have sensitivity to the β rays L. The first scintillator 20A, the second scintillator 20B, the first photoelectric conversion layer 24A, and the second photoelectric conversion layer 24B can be suppressed from having sensitivity to radiations (for example, γ rays) other than the β rays L.

The thickness of the second scintillator 20B is larger than the thickness of the first scintillator 20A. Accordingly, in the radiation detector 10A in the embodiment, the first scintillator 20A preferentially coverts, into the first scintillation light S1, the β rays LA in the lower energy band, and the second scintillator 20B preferentially coverts, into the second scintillation light S2, the β rays LB in the higher energy band.

The radiation detector 10A in the embodiment can therefore detect the β rays L in various energy bands. That is to say, the radiation detector 10A in the embodiment can suppress the β rays in at least some energy bands out of the β rays L in various energy bands from being undetectable.

Accordingly, the radiation detector 10A in the embodiment can therefore improve detection accuracy of the β rays L.

### Second Embodiment

The configuration of the radiation detector 10 is not limited to the configuration of the radiation detector 10A in the above-mentioned first embodiment. The radiation detector 10 may further include a reflection layer.

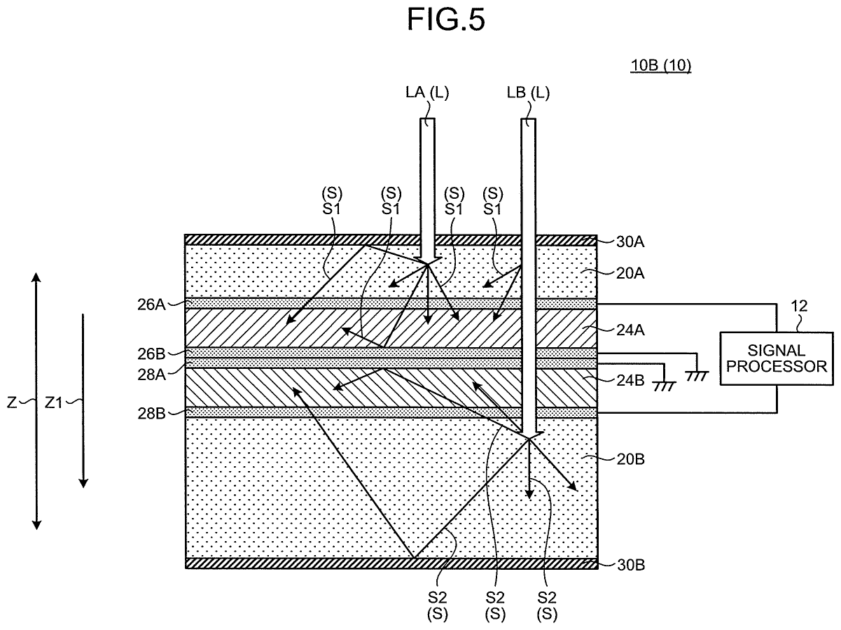

FIG. 5 is a schematic diagram illustrating an example of the radiation detection 10B in the embodiment. The radiation detector 10B is an example of the radiation detector 10. Radiation Detector 10B

The radiation detector 10B includes the first scintillator 20A, the second scintillator 20B, the first photoelectric conversion layer 24A, the second photoelectric conversion layer 24B, the first electrode layer 26A, the second electrode layer 26B, the third electrode layer 28A, the fourth electrode layer 28B, a first reflection layer 30A, and a second reflection layer 30B.

The first scintillator 20A, the second scintillator 20B, the first photoelectric conversion layer 24A, the second photoelectric conversion layer 24B, the first electrode layer 26A, the second electrode layer 26B, the third electrode layer 28A, and the fourth electrode layer 28B are the same as those in the first embodiment. That is to say, the radiation detector 10B in the embodiment further includes the first reflection layer 30A and the second reflection layer 30B in addition to the radiation detector 10A in the first embodiment.

The first reflection layer 30A is arranged on the upstream side relative to the first scintillator 20A in the incident direction Z1 of the β rays L. The first reflection layer 30A transmits at least a part ofβ rays L and reflects at least a part of the first scintillation light S1.

It is sufficient that the first reflection layer 30A is formed with a material satisfying the above-mentioned characteristics. For example, the first reflection layer 30A is preferably formed using aluminum from the viewpoint of transmissivity of radiations and reflectivity of scintillation light.

The thickness of the first reflection layer 30A is not limited. Although the thickness of the first reflection layer 30A is, for example, 10 nm to 1 μm, it is not limited thereto.

The second reflection layer 30B is arranged on the downstream side relative to the second scintillator 20B in the incident direction Z1 of the β rays L. The second reflection layer 30B reflects at least a part of the first scintillation light S1.

It is sufficient that the second reflection layer 30B is formed with a material satisfying the above-mentioned characteristics. For example, the second reflection layer 30B is preferably formed using aluminum from the viewpoint of transmissivity of radiations and reflectivity of scintillation light.

The thickness of the second reflection layer 30B is not limited. Although the thickness of the second reflection layer 30B is, for example, 10 nm to 1 μm, it is not limited thereto.

### Actions of Radiation Detector 10B

Next, actions of the radiation detector 10B will be described.

Theβ rays L are incident on the radiation detector 10B and reach the first scintillator 20A. The first scintillator 20A converts, into the first scintillation light 51, the β rays L incident on the first scintillator 20A. The first scintillation light S1 converted by the first scintillator 20A reaches the first photoelectric conversion layer 24A. The first photoelectric conversion layer 24A converts the incident first scintillation light S1 into electric charges as in the first embodiment.

In the embodiment, the first reflection layer 30A is provided on the upstream side relative to the first scintillator 20A in the incident direction Z1 of the β rays L. The first scintillation light S1 that has been converted by the first scintillator 20A and has reached the first reflection layer 30A is reflected by the first reflection layer 30A and reaches the first photoelectric conversion layer 24A through the first scintillator 20A and the first electrode layer 26A.

Thus, provision of the first reflection layer 30A enables the first photoelectric conversion layer 24A to convert the first scintillation light S1 into the electric charges efficiently.

On the other hand, at least a part of the β rays LB in a higher energy band out of the β0 rays L incident on the radiation detector 10A passes through the first scintillator 20A and reaches the second scintillator 20B.

The second scintillator 20B converts, into the second scintillation light S2, the β rays LB incident on the second scintillator 20B. The second scintillation light S2 converted by the second scintillator 20B reaches the second photoelectric conversion layer 24B. The second photoelectric conversion layer 24B converts the incident second scintillation light S2 into electric charges as in the first embodiment.

In the embodiment, the second reflection layer 30B is provided on the downstream side relative to the second scintillator 20B in the incident direction Z1 of the β rays L. The second scintillation light S2 that has been converted by the second scintillator 20B and has reached the second reflection layer 30B is reflected by the second reflection layer 30B and reaches the second photoelectric conversion layer 24B through the second scintillator 20B and the fourth electrode layer 28B.

Thus, provision of the second reflection layer 30B enables the second photoelectric conversion layer 24B to convert the second scintillation light S2 into the electric charges efficiently.

It is sufficient that the radiation detector 10B includes at least one of the first reflection layer 30A and the second reflection layer 30B. The radiation detector 10B is not therefore limited to a mode including both of the first reflection layer 30A and the second reflection layer 30B. It is however preferable that the radiation detector 10B include both of the first reflection layer 30A and the second reflection layer 30B from the viewpoint of efficient conversion of the scintillation light S into the electric charges.

As described above, the radiation detector 10B in the embodiment includes at least one of the first reflection layer 30A and the second reflection layer 30B in addition to the components of the radiation detector 10A in the first embodiment.

The first reflection layer 30A is arranged on the upstream side relative to the first scintillator 20A in the incident direction Z1 of the β rays L and transmits at least a part of the β rays L and reflects at least a part of the first scintillation light S1. The second reflection layer 30B is arranged on the downstream side relative to the second scintillator 20B in the incident direction Z1 of the β rays L and reflects at least a part of the second scintillation light S2.

The radiation detector 10B in the embodiment can therefore improve conversion efficiency of the scintillation light S into the electric charges in addition to the effects in the above-mentioned first embodiment.

### Hardware Configuration

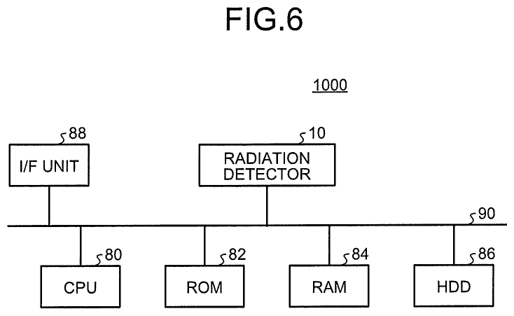

Next, the hardware configuration of the radiation detection apparatus 1000 in the above-mentioned embodiments will be described. FIG. 6 is a block diagram illustrating an example of the hardware configuration of the radiation detection apparatus 1000 in the above-mentioned embodiments.

The radiation detection apparatus 1000 in the above-mentioned embodiments has the hardware configuration, using a common computer, in which a CPU 80, a read only memory (ROM) 82, a random access memory (RAM) 84, a hard disk drive (HDD) 86, an interface (I/F) unit 88, and the radiation detector 10 are connected to one another via a bus 90.

The CPU 80 is an arithmetic device controlling the entire processing of the radiation detection apparatus 1000. The RAM 84 stores therein pieces of data necessary for various types of processing by the CPU 80. The ROM 82 stores therein computer programs and the like implementing various types of processing by the CPU 80. The HDD 86 stores therein pieces of data stored in the above-mentioned storage unit 14. The I/F unit 88 is an interface connected to the external apparatus or an external terminal via a communication line or the like and transmits and receives pieces of data to and from the connected external apparatus and external terminal.

The computer programs for executing the above-mentioned pieces of processing that the radiation detection apparatus 1000 in the above-mentioned embodiments executes is previously incorporated and provided in the ROM 82 or the like.

The computer programs that the radiation detection apparatus 1000 in the above-mentioned embodiment executes may be recorded and provided in a computer-readable recording medium such as a compact disc read only memory (CD-ROM), a flexible disk (FD), a compact disc recordable (CD-R), and a digital versatile disc (DVD) as an installable or executable file in the apparatus.

The computer programs that the radiation detection apparatus 1000 in the above-mentioned embodiments executes may be stored in a computer connected to a network such as the Internet and provided by being downloaded via the network. The computer programs that the radiation detection apparatus 1000 in the above-mentioned embodiments executes may be provided or distributed via the network such as the Internet.

The above-mentioned units generate, on a main storage unit, the computer programs for executing the above-mentioned pieces of processing that the radiation detection apparatus 1000 in the above-mentioned embodiments executes.

Various types of information stored in the above-mentioned HDD 86, that is, various types of information stored in the storage unit 14 may be stored in the external apparatus (for example, a server). In this case, it is sufficient that the external apparatus and the CPU 80 are connected through the I/F unit 88.

While certain embodiments have been described, these embodiments have been presented by way of example only, and are not intended to limit the scope of the inventions. Indeed, the novel devices and apparatuses described herein may be embodied in a variety of other forms; furthermore, various omissions, substitutions and changes in the form of the devices and apparatuses described herein may be made without departing from the spirit of the inventions. The accompanying claims and their equivalents are intended to cover such forms or modifications as would fall within the scope and spirits of the inventions.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A radiation detector comprising:
a first scintillator to convert β rays into first scintillation light;
a second scintillator to convert the β rays into second scintillation light;
a first photoelectric conversion layer, provided between the first scintillator and the second scintillator, to convert the first scintillation light into electric charges; and
a second photoelectric conversion layer, provided between the first photoelectric conversion layer and the second scintillator, to convert the second scintillation light into electric charges, wherein
the first scintillator, the second scintillator, the first photoelectric conversion layer, and the second photoelectric conversion layer are each formed with an organic material as a main component, and
a thickness of the second scintillator is larger than a thickness of the first scintillator.

2. The radiation detector according to claim 1, wherein the β rays are emitted from radioactive materials of a plurality of types.

3. The radiation detector according to claim 1, wherein
the thickness of the first scintillator is equal to or larger than 0.1 mm and equal to or smaller than 0.9 mm, and
the thickness of the second scintillator is equal to or larger than 1 mm and equal to or smaller than 4 mm.

4. The radiation detector according to claim 3, wherein the β rays are emitted from Sr-90 and Cs-137.

5. The radiation detector according to claim 1, wherein
the thickness of the first scintillator is smaller than a thickness capable of converting γ rays into the first scintillation light, and
the thickness of the second scintillator is smaller than a thickness capable of converting the γ rays into the second scintillation light.

6. The radiation detector according to claim 1, wherein densities of the first scintillator and the second scintillator are equal to or lower than 2.0 g/cm³.

7. The radiation detector according to claim 1, wherein densities of the first photoelectric conversion layer and the second photoelectric conversion layer are equal to or lower than 2.0 g/cm³.

8. The radiation detector according to claim 1, wherein
the first photoelectric conversion layer is arranged between a first electrode layer and a second electrode layer, and
the second photoelectric conversion layer is arranged between a third electrode layer and a fourth electrode layer.

9. The radiation detector according to claim 8, wherein
the first electrode layer is arranged between the first scintillator and the first photoelectric conversion layer, transmits at least a part of the 0 rays, and transmits at least a part of the first scintillation light, and
the second electrode layer is arranged between the first photoelectric conversion layer and the second photoelectric conversion layer, transmits at least a part of the β rays, and reflects at least a part of the first scintillation light.

10. The radiation detector according to claim 8, wherein
the third electrode layer is arranged between the second photoelectric conversion layer and the second electrode layer, transmits at least a part of the β rays, and reflects at least a part of the second scintillation light, and
the fourth electrode layer is arranged between the second photoelectric conversion layer and the second scintillator, transmits at least a part of the β rays, and transmits at least a part of the second scintillation light.

11. The radiation detector according to claim 1, comprising at least one of:
a first reflection layer arranged on an upstream side relative to the first scintillator in an incident direction of the β rays, transmits at least a part of the β rays, and reflects at least a part of the first scintillation light, and
a second reflection layer arranged on a downstream side relative to the second scintillator in the incident direction of the β rays and reflects at least a part of the second scintillation light.

12. A radiation detection apparatus comprising:
the radiation detector according to claim 1;
a calculation unit to calculate, as an evaluation value of incident β rays, a signal ratio between a first output signal with the electric charges resulting from conversion by the first photoelectric conversion layer and a second output signal with the electric charges resulting from conversion by the second photoelectric conversion layer; and
a specifying unit to specify, as a detection result, a type of a radioactive material emitting the β rays and incident energy of the β rays that correspond to the calculated evaluation value in a conversion table in which the evaluation value, the type of the radioactive material, and the incident energy are associated with one another.
